(19) United States
(12) Patent Application Publication
(10) Pub. No.: US 2025/0275101 A1
(43) Pub. Date: Aug. 28, 2025

(54) ZERO-U COOLANT DISTRIBUTION UNIT

(71) Applicant: Vertiv Corporation, Westerville, OH (US)

(72) Inventors: Brad Lee Wilson, Centennial, WY (US); Jeremy Ryan King, Delaware, OH (US)

(21) Appl. No.: 18/754,124

(22) Filed: Jun. 25, 2024

Related U.S. Application Data
(63) Continuation-in-part of application No. 18/583,963, filed on Feb. 22, 2024.

(51) Int. Cl. H05K 7/20

(52) U.S. Cl. CPC H05K 7/20763; H05K 7/20836; H05K 7/20254; H05K 7/20272

(57) ABSTRACT

A server rack assembly is disclosed. The server rack assembly includes: a housing in which a rack is enclosed; a first server disposed on the rack and configured to support a heat-generating electronic device, the first server having a cold plate disposed on the heat-generating electronic device and a pump fluidically communicating with the cold plate via a liquid distribution loop; and a first coolant distribution unit (CDU) configured to be assembled to the first server. The first CDU is configured to be in contact with the liquid distribution loop and comprises an inlet and an outlet.

### CROSS-REFERENCE TO RELATED APPLICATIONS

This application is a Continuation-in-Part of U.S. patent application Ser. No. 18/583,963, filed on Feb. 22, 2024, entitled “ZERO-U COOLANT DISTRIBUTION UNIT,” which claims benefit of priority to U.S. Provisional Application Ser. No. 63/486,346, entitled “ZERO-U COOLANT DISTRIBUTION UNIT,” filed Feb. 22, 2023, and which are herein incorporated by reference.

### TECHNICAL FIELD

The present disclosure relates to heat rejection systems, and more specifically, to high-density heat rejection systems for use with data centers.

### BACKGROUND

As demands for computing power continue to grow, so too do the demands for energy and cost-efficient cooling methods. This need is particularly critical in computer cabinet systems, where many rack-mounted computing systems are arranged in a high-density environment, resulting in large amounts of heat which can limit the viability of air cooling. Current solutions for these cabinets can include an array of fans moving excess heat out of the cabinet into the room where the cabinet is located, in combination with computer-room air conditioners that cool the warm air.

Such server cooling in data centers is transitioning from air cooling to more efficient fluid cooling solutions. Fluid cooling also known as liquid cooling can bring several benefits including reducing energy costs, reducing the carbon footprint, increasing power density, higher cooling requirements, targeted cooling options, and significantly improved heat transfer (water has 4,000 times the heat capacity compared to the same volume of air), thus greatly enhancing energy efficiency, and improved possibilities for utilizing waste heat, thereby significantly reducing the power usage effectiveness (PUE) of a data center. Moreover, more efficient cooling allows for more powerful server components, including higher processor clock speeds, substantially increasing power density within servers and entire data centers.

Current liquid cooling solutions use coolant distribution units (CDUs) which coordinate the flow and distribution of liquid coolant throughout the computing systems. The CDUs however can take up valuable floor space that can otherwise be occupied by additional computing systems. The need for taking up less floor space can be addressed by rack-mounted CDUs that are mounted in the same rack as the computing systems. Typically, a rack-mounted CDU is mounted at the top or bottom of the rack within a computing cabinet. While rack-mounting a CDU does provide benefits such as reducing the floor footprint of cooling equipment, rack-mounted CDUs still occupy valuable server rack space. For instance, the rack-mounting configuration makes it possible to reduce the CDU's footprint within the computer cabinet and data center, but at the expense of other components that can occupy more space within a standard rack including infrastructure such as a network switch or UPS or additional computing systems. Thus, utilizing a rack-based CDU can significantly limit the total number of devices that can exist in a standard rack.

Therefore, there exists a need for a smaller footprint CDU that does not restrict the space where other computing devices can be mounted.

### SUMMARY

This section provides a general summary of the disclosure and is not a comprehensive disclosure of its full scope or all of its features. The present disclosure relates to computer hardware cabinets, and more particularly, this disclosure relates to the placement of a cooling apparatus within a computer hardware cabinet.

In an embodiment, the present disclosure is directed toward a server rack assembly. The server rack assembly includes: a housing in which a rack is enclosed; a first server disposed on the rack and configured to support a heat-generating electronic device, the first server having a cold plate disposed on the heat-generating electronic device and a pump fluidically communicating with the cold plate via a liquid distribution loop; and a first coolant distribution unit (CDU) configured to be assembled to the first server, the first CDU being in contact with the liquid distribution loop and includes an inlet and an outlet. In some embodiments, the pump may direct a technical fluid to flow from the pump, to the cold plate, and back to the pump.

In some embodiments, the server rack assembly may further include: a second server configured to be disposed adjacent the first server on the rack, the second server having a pump, a cold plate, and a liquid distribution loop therebetween; and a second CDU configured to be assembled to the second server. An inlet and an outlet of the second CDU and the inlet and the outlet of the first CDU, respectively, are configured to correspond to each other. In some embodiments, the server rack assembly may further include: a third server configured to be disposed adjacent the second server on the rack, the third server having a pump, a cold plate, and a liquid distribution loop therebetween; and a third CDU configured to be assembled to the third server. An inlet and an outlet of the third CDU and the inlet and the outlet of the second CDU, respectively, are configured to correspond to each other.

In some embodiments, the first to third CDUs are disposed in a space adjacent the first to third servers within the housing. The server rack assembly further includes: a controller and a sensor communicating with each of the first to third CDUs and the first to third servers; and a user interface on the controller for manual control and monitoring of cooling parameters. The controller may control the fluid to partly flow vertically through inlets of the first to third CDUs and to partly flow laterally from the inlets to the outlets, respectively, of the first to third CDUs.

In some embodiments, an amount and a flow rate of fluid flowing through the first to third CDUs are controlled by the controller based on sensing data received from the sensor. The sensing data includes at least one of a cold plate status, a fluid flow rate, a heat-generating electronic device status, a fluid temperature, or a fluid particle size. In some embodiments, based on the sensing data, the controller is configured to selectively control the pumps of the respective first to third servers.

In some embodiments, when the sensing data detected by the first server is outside a threshold, the controller turns off the pump of the first server, and when the sensing data detected by the second server is outside a threshold, the controller turns off the pump of the second server. The first server may further include a second cold plate disposed on a second heat-generating electronic device. The first server may further include a second pump, the first and second pumps communicating with the first and second cold plates, respectively, on the first server. The inlet has an opening at a bottom side of the CDU and the outlet has an opening at a top side of the CDU.

In an embodiment, the present disclosure is also directed toward a server rack assembly for liquid cooling. The server rack assembly contains a housing with at least one rack configured to support heat generating devices, a front space region, a rear space region, and a plurality a side walls. The server rack assembly includes: at least two cold plates disposed on heat-generating electronic devices, respectively; a pump configured to provide a technical fluid to the least two cold plates via a supply fluid path and receive the technical fluid that passes through the least two cold plates via a return fluid path; and a heat exchanger extending along one side of the server. The heat exchanger may include a main body.

In some embodiments, the heat exchanger includes an inlet, an outlet, and a main body extending between the inlet and the outlet. The heat exchanger may be configured as a tube through which a fluid passes from the inlet to the outlet, and the main body of the heat exchanger is in direct contact with the return fluid path. In some embodiments, the inlet and the outlet of the heat exchanger are configured to correspond to an inlet and an outlet of another heat exchanger, respectively, to be assembled.

Other aspects and advantages of the invention will become apparent from the following detailed description, taken in conjunction with the accompanying drawings, illustrating by way of example the principles of the invention.

### BRIEF DESCRIPTION OF THE DRAWINGS

The disclosure will be readily understood by the following detailed description in conjunction with the accompanying drawings, wherein like reference numerals designate like elements:

FIG. 1A illustrates a front perspective view of an enclosed server rack cabinet according to an embodiment of the present disclosure;

FIG. 1B illustrates a rear view of an open server cabinet including a rack and a rear mounted coolant distribution unit (CDU) according to an embodiment of the present disclosure;

FIG. 2A illustrates a perspective view of a vertical oriented CDU according to an embodiment of the present disclosure;

FIG. 2B illustrates an opened view of the CDU of FIG. 2A showing internal components therein according to an embodiment of the present disclosure;

FIG. 3 illustrates a schematic diagram of a cooling system in a data center according to an embodiment of the present disclosure;

FIG. 4 illustrates a perspective view of a single stackable CDU connected to a server according to another embodiment of the present disclosure;

FIG. 5 illustrates several CDUs of FIG. being stacked against each other according to another embodiment of the present disclosure; and

FIGS. 6A and 6B illustrate an enclosed server rack cabinet having the CDUs with servers and without servers, respectively, installed in a cabinet according to another embodiment of the present disclosure.

### DETAILED DESCRIPTION

Aspects of the disclosure are described more fully hereinafter with reference to the accompanying drawings, which form a part hereof, and which show, by way of illustration, example features. The features can, however, be embodied in many different forms and should not be construed as limited to the combinations set forth herein; rather, these combinations are provided so that this disclosure will be thorough and complete and will fully convey the scope. The following detailed description is, therefore, not to be taken in a limiting sense.

The use of a singular term, such as, but not limited to, “a,” is not intended as limiting of the number of items. The use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the inventions or the appended claims. The terms “including” and “such as” are for illustrative purposes but not limited thereto. The terms “couple,” “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and can further include without limitation integrally forming one functional member with another in a unity fashion. The coupling can occur in any direction, including rotationally. Further, all parts and components of the disclosure that are capable of being physically embodied inherently include imaginary and real characteristics regardless of whether such characteristics are expressly described herein, including but not limited to characteristics such as axes, ends, inner and outer surfaces, interior spaces, tops, bottoms, sides, boundaries, dimensions (e.g., height, length, width, thickness), mass, weight, volume, and density, among others.

Servers have become very important, particularly since institutions, companies and consumers use the Cloud daily. The number of data centers keeps increasing. Servers also become more and more powerful and therefore, generate more and more heat. While still widely used in data centers, the potential of traditional air-cooling systems is limited, more so when taking the impact on the environment into account. A few technologies based on liquid emerged, among them is direct liquid cooling (DLC), also called direct-to-chip liquid cooling. With this technique, only high power-consuming components are cooled: processors, graphics cards, etc. The principle of the DLC is to establish a cooling loop. Cold liquid is sent to cold plates, mounted directly on the hot electronic components, and absorbs the heat which is sent to a coolant distribution unit (CDU) to a heat exchanger whose function is to dissipate the heat. They are usually located in the rack or shared by rows. When the liquid has been cooled, it is returned to the cold plates, thus closing the cooling loop. Practically, not all the heat generated by the processors is removed through liquid cooling, and there is still some percentage of heat removed by air cooling. Thus the entire environment is a hybrid liquid-air cooling system.

CDUs are essential components that ensure liquid-cooled systems meet expectations. Operation logic integrated into intelligent controllers combined with smart control manage server and data center cooling system performance. CDUs contain a pump that circulates coolant through a network of pipes or channels, distributing it to various components like servers, processors, or other high-heat components in large, high-power devices that need cooling. CDUs may also contain valves, filters, and other components to control and monitor coolant flow.

The present disclosure offers a space-saving solution for CDUs that are housed within data center cabinets. In addition to electronic computing devices mounted on a rack within a cabinet, a CDU can also be mounted on a rack to provide liquid cooling functionality to the electronic computing devices. The space that a rack-mounted electronic device occupies on a rack is measured in standard units of about, e.g., 2.5 cm, often referred to as a “rack unit” or a “u space.” When an electronic device is mounted in a location not on the rack, it is considered to be “zero u” since it takes up no space within the internal rack housing. The present disclosure allows for a CDU to be mounted behind a rack in the rear space of a cabinet, whereas it can be considered a “zero u” CDU.

Further, the present disclosure can reduce the blast radius of pump failure to single cold plates within individual servers with a simpler, higher-resilient product. By incorporating our rack manifold into the CDU design, it is possible to simplify a secondary fluid network by combining the CDU and the manifold into a single element.

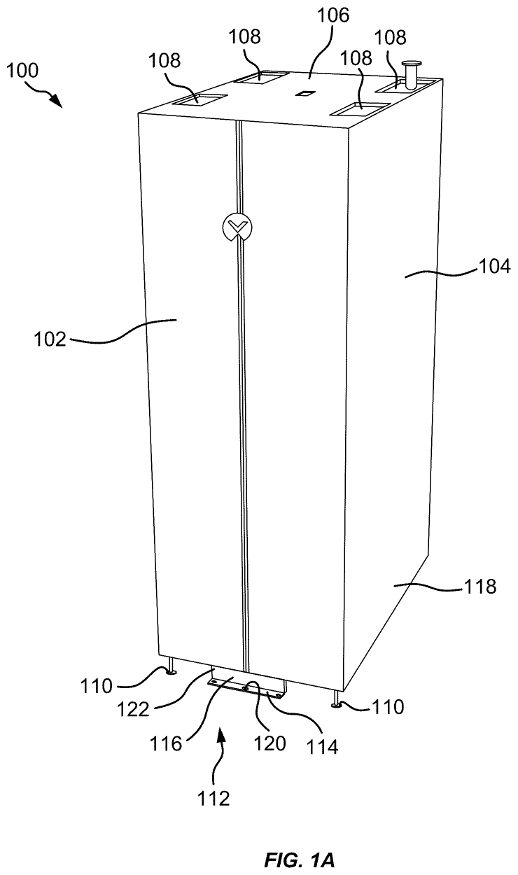

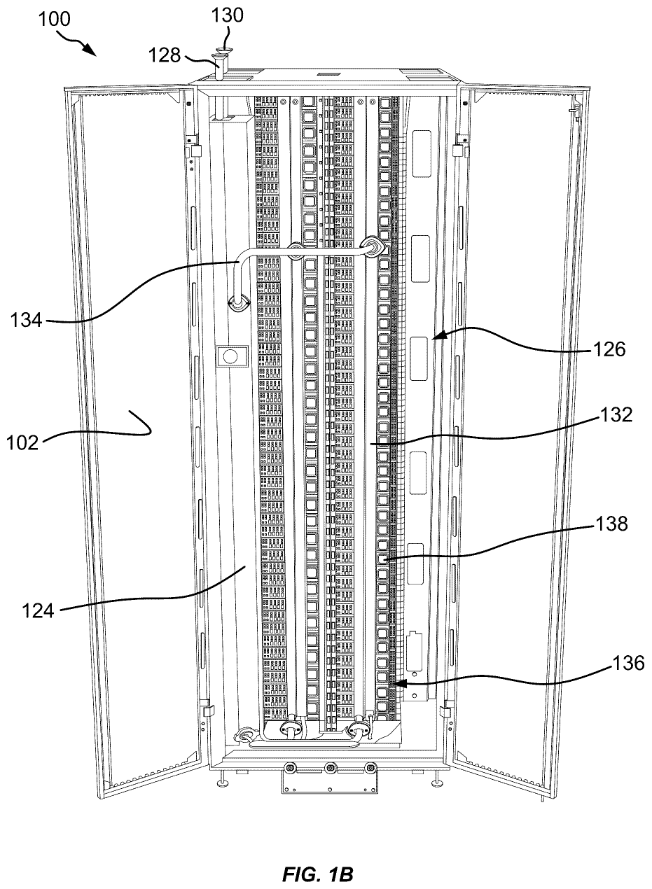

Shown throughout the figures, the present disclosure is directed towards a computer cabinet that utilizes a “zero u” CDU. Referring initially to FIGS. 1A and 1B, a computer cabinet 100 is illustrated in accordance with an exemplary embodiment of the present disclosure.

### Single Body CDU

FIG. 1A is a front orthogonal view illustrating a computer cabinet 100 according to one embodiment of the present disclosure. The computer cabinet 100 includes a front door 102 in a closed position, at least one side panel 104, and a top panel 106. The computer cabinet 100 also includes top openings 108 included in the top panel 106 that can accommodate input and exhaust features of internal cabinet components. For example, chilled water, refrigerant, or other types of heat-carrying fluids can be supplied to components in the interior of the computer cabinet 100. As depicted, the bottom of computer cabinet 100 includes risers 110 to separate the computer cabinet 100 from the ground and facilitate airflow capabilities in and around the computer cabinet 100. The risers 110 can be located at the four corners of the cabinet 100 as depicted. The computer cabinet 100 further includes a stabilizing plate 112 that provides the ability for the computer cabinet 100 to be securely fastened to the floor. For example, the stabilizing plate 112 can improve stability by anchoring the computer rack 100 to a fixed point. Certain regulatory requirements can require the use of a stabilizing plate 112 that prevents tipping over in response to unwanted forces, such as seismic force, inadvertent contact by a person, or forces applied when making changes within the computer cabinet 100. The stabilizing plate 112 includes a horizontal base plate 114 and a vertical plate 116 attached to the base 118 of the computer cabinet 100. The horizontal base 114 includes a number of floor mounting holes 120. The vertical plate 116 includes a number of cabinet mounting holes 122. The floor mounting holes 120 can facilitate the use of fasteners to affix the computer rack 100 to a fixed point such as the ground or a structure fixed to the ground.

FIG. 1B is a rear view illustrating the computer cabinet 100 with rear doors 102 in an open position revealing the interior of the cabinet 100. Further depicted is a coolant distribution unit (CDU) 124 located within the interior of the computer cabinet 100. In the present embodiment, the CDU 124 is located in a rear space 126 of the computer cabinet 100, close to the rear doors 102. The CDU 124 can include an input conduit 128 and an exhaust conduit 130. In an embodiment, the input conduit 128 and the exhaust conduit 130 can extend from the interior to the exterior of the computer cabinet 100 via a top opening 108. The conduits 128, 130 can respectively supply chilled water to the CDU 124 and carry away warmed water from the CDU 124. In other embodiments, other refrigerants can be respectively supplied and carried away from the CDU 124, including water/glycol, or any compatible sensible phase liquid.

FIG. 1B also illustrates a manifold 132 that extends down the vertical length of the computer cabinet 100. In an embodiment, the manifold 132 can carry coolant to and from the CDU 124 to cool systems within the computer cabinet 100. The CDU 124 can be connected to the manifold 132 via a flexible hose 134. There further exists an array of couplings down the vertical length of the manifold 132 by which the electronic equipment within the computer cabinet 100 can be fluidly coupled with the CDU 124.

Further, FIG. 1B illustrates a server rack 136 that is housed on the interior of the computer cabinet 100. The server rack 136 is capable of securely holding rack mountable systems 138. In embodiments, the rack mountable system 138 can, by way of example, be a server blade, a power supply unit, a keyboard, video, and mouse (KVM) switch, or a network patch panel. In addition, the rack mountable systems 138 can be secured to the server rack 136 in a repeatable fashion that can present components also in a known, repeatable fashion. For example, the rack mountable system 138 can include a coupling extending from the rear portion that is presented in a known, repeatable fashion by virtue of the method of mounting the rack mountable system 138 to the server rack 136. In this way, the rack mountable system 138 can be connected to the manifold 132 via a coupling to allow coolant distributed from the CDU 124 to cool the rack mountable system 138. In addition, the rack mountable system 138 can include networking and power cables extending from the rear in a known, repeatable fashion, allowing for simpler and safer cable replacement or repair.

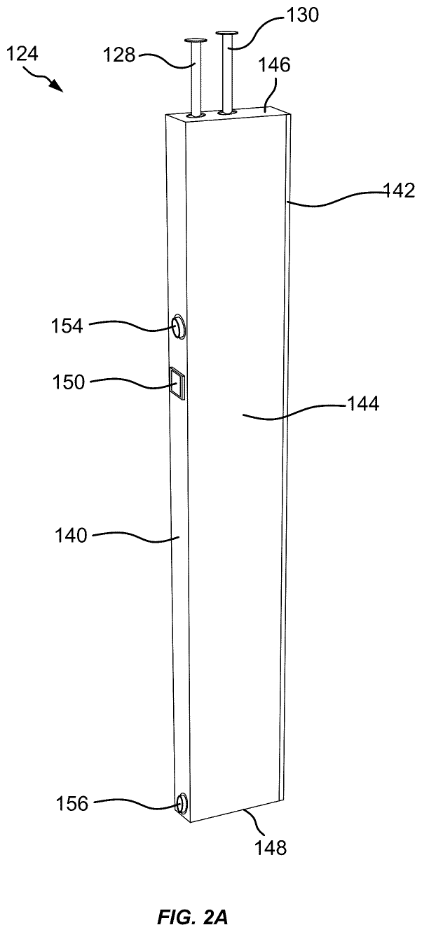

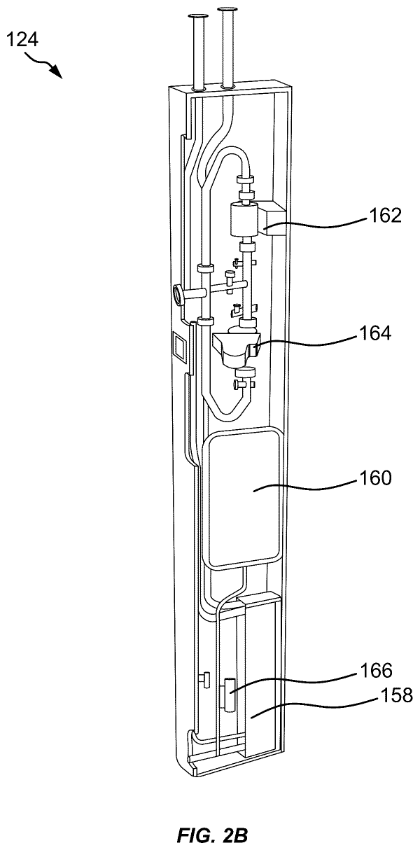

FIG. 2A illustrates a coolant distribution unit (CDU) 124. The CDU includes a front panel 140, a rear panel 142, side panels 144, a top panel 146, and a bottom panel 148 that cooperate to define a housing for the CDU 124. The panels 140, 142, 144, 146, and 148 can be constructed with a sheet metal or composite material. The CDU 124 further includes an intake conduit 128, and an exhaust conduit 130. As depicted, the conduits 128, 130 connect the interior of the CDU 124 to the exterior through top panel 146. In an embodiment, the vertical distance from the top panel 146 to the bottom panel 148 is greater than the horizontal distance from the front panel 140 to the rear panel 142.

As shown in FIG. 2A, in an exemplary embodiment, the CDU 124 includes a human machine interface (HMI) 150 located on the front panel 140. The HMI 150 can be connected to an electronic control system 152 of the CDU 124. The HMI 150 is capable of allowing user input to control CDU 124 features such as changing coolant flow rates, coolant flow pressures, or turning the CDU 124 on and off. Further, the HMI 150 is capable of displaying critical information related to the operation of the CDU, such as warnings, alarms, and temperature information of the coolant and the electronic systems within the cabinet 100. However, it is to be understood that the HMI 150 can be configured to display any information captured by the CDU 124 during its operation. The HMI 150 can also be a logo plate. It is further contemplated that the CDU 124 can include both HMI 150 and logo plate in the same location on the computer cabinet 100.

FIG. 2A further shows an upper manifold connection point 154 and a lower manifold connection point 156. The upper manifold connection point 154 can be positioned on the front panel 140 proximal to the top panel 146 of the CDU 124. The lower manifold connection point 156 can be positioned on the front panel 140 proximal to the bottom panel 148 of the CDU 124. In an embodiment, a flexible hose 134 can be connected to the CDU 124 at the upper manifold connection point 154 and connected to the rack. The flexible hose 134 is configured to carry cooled coolant from the CDU 124 to the rack manifold in order to absorb the heat produced by the electronic systems therein. In an exemplary embodiment, the electronic systems therein can include a uniform coupling extending from the rear portion, allowing for a consistent attachment point to the rack manifold. Further, a flexible hose can be connected to the rack manifold and the lower manifold connection point 156. This flexible hose is configured to carry warmed coolant from the rack manifold to the CDU 124. It is to be understood, however, that a fixed hose can be used in place of a flexible hose to carry coolant from the CDU 124 to the rack and from the rack to the CDU 124. A fixed hose can make it easier for a user to effectively organize cables extending from the rear of the computer cabinet 100. It is also to be understood that the length of the fixed hose or flexible hose can be any length required to comfortably connect the CDU 124 to the computer cabinet 100.

FIG. 2B illustrates an interior view of a CDU 124. The CDU 124 can consist of a heat exchanger 158, an expansion tank 160, an upper pump 162, a lower pump, for redundancy 164, and a control valve 166. In an embodiment, the heat exchanger 158 is a brazed plate heat exchanger. The heat exchanger 158 can be located proximate to the rear panel 142 and bottom panel 148 of the CDU 124. The intake conduit 128 receives coolant from an external source and passes the coolant through the CDU 124 until the coolant exits via a flexible tube to the manifold 132. The exhaust conduit 130 takes used coolant from the manifold 132 that passes through the heat exchanger 158 to a location outside of the CDU 124 to be recycled and used again as coolant, once the heat has been removed from the coolant.

FIG. 2B further illustrates the relative position of the interior components of the CDU 124. Previously, the packaging and desired use cases of rack mounted CDUs necessitated a horizontal orientation of internal components, such that CDUs are sized and dimensioned to be mountable within standard server rack space. However, due to the vertical orientation of the CDU 124, the relative position of the interior components contributes to and increases the operational efficiency of the CDU 124. In an exemplary embodiment, the heat exchanger 158 is located below all other major components. Since the coolant moves down the rack within the cabinet 100, the coolant eventually reenters the CDU 124 at the bottom of the cabinet via connection 156. The cold facility side water flow is controlled by valve 166, thereby regulating the heat exchanger in order to achieve the desired temperature change. Accordingly, the heat exchanger is positioned within the bottom of the CDU 124. Further, the expansion tank 160 is located proximately above the heat exchanger 158. The expansion tank 160 is connected to the warm return piping from the manifold and prevents excessive water pressure by handling the thermal expansion of water. The upper pump 162 and lower redundant pump 164 are located above the expansion tank 160 and proximate to the manifold supply connection point 154. The outlet of the pumps 162, 164 are connected to connection point 154 and are configured to modify the flow rate in response to temperature fluctuations of the coolant or user input from the HMI 150. The pump operation flows out to the rack manifold via connection 154.

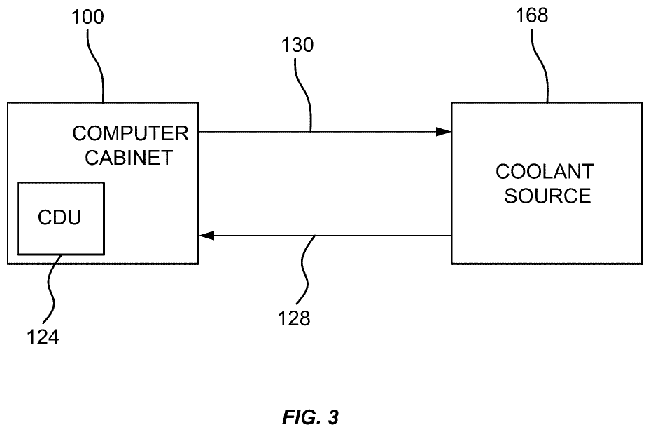

FIG. 3 shows a schematic diagram of a data center that utilizes a zero-u coolant distribution 124. The CDU 124 is mounted within the rear space 126 of the computer cabinet 100. A coolant source 168 can be located within the data center facility or outside of the data center facility. The coolant source 168 can be a cold water tank, a computer room air conditioning unit (CRAC), or a geothermal source. The CDU 124 receives coolant from the coolant source 168 via the input conduit 128. The received coolant is then distributed by the CDU 124 to electronic systems mounted in the computer cabinet 100. Once the rack mountable systems 138 within the cabinet 100 are cooled, the CDU 124 sends the coolant, via the exhaust conduit 130, back to the coolant source 168 where it can be recycled for use again, once the heat has been removed from the coolant.

### Stackable CDU

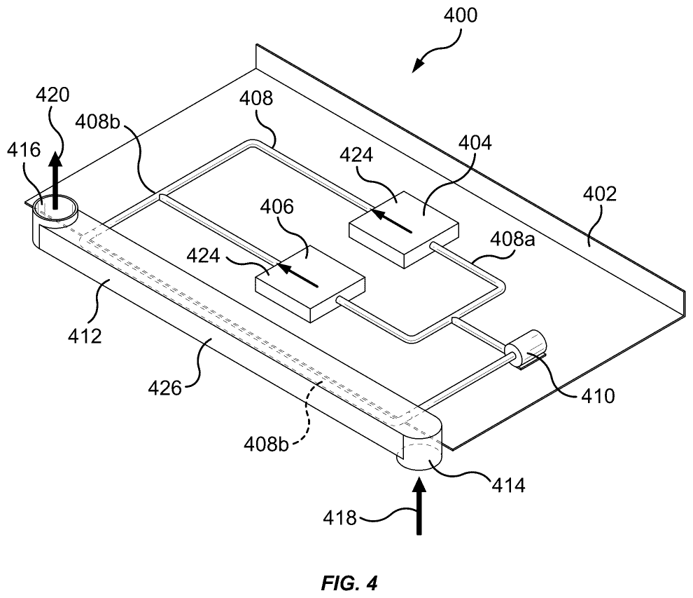

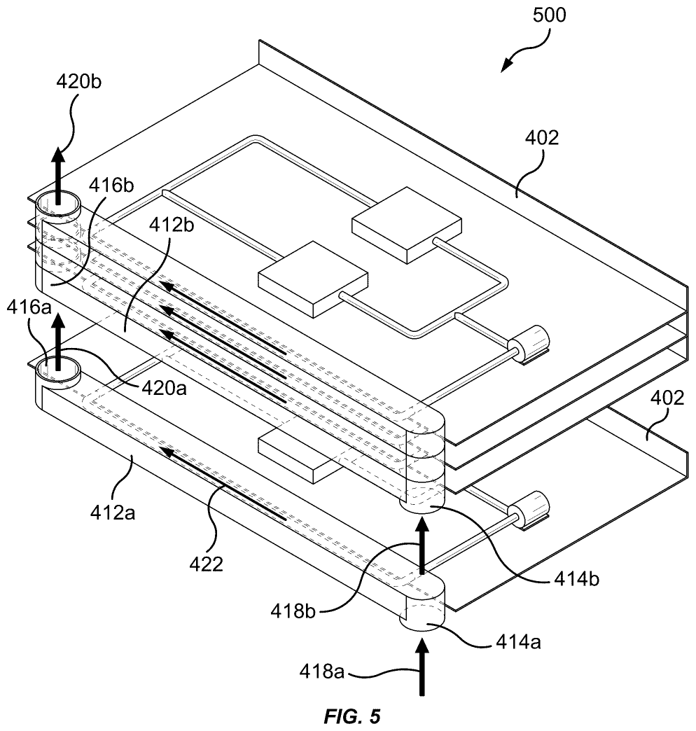

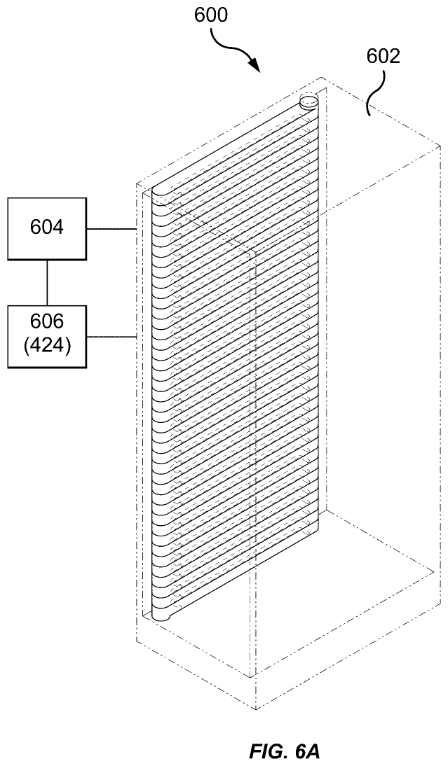

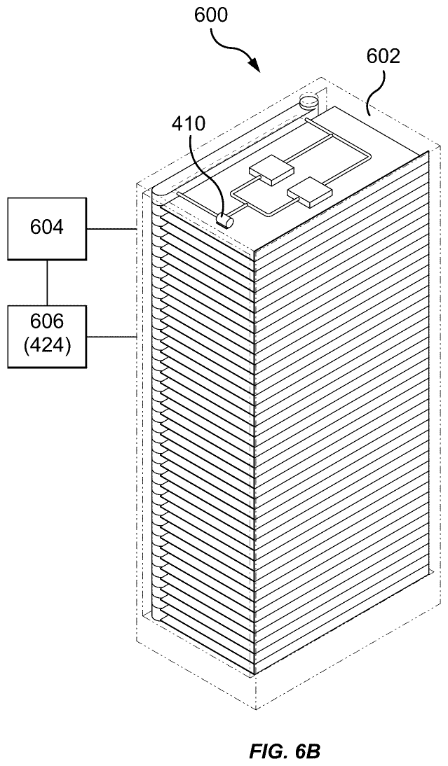

FIG. 4 illustrates a perspective view of a single stackable CDU connected to a server according to another embodiment of the present disclosure. FIG. 5 illustrates several CDUs being stacked against each other. FIGS. 6A and 6B illustrate an enclosed server rack cabinet having the CDUs with and without servers, respectively, installed in the system.

The single-body CDU described above with reference to FIGS. 1A-3 is configured as one housing having several components, e.g., heat exchanger 158, tank 160, pumps 162, 164, coolant source 168, therein as shown in FIG. 2B. On the other hand, the stackable CDU described hereinbelow with reference to FIGS. 4-6B is a heat exchanger unit/s/ through which cold fluid, e.g., chilled water, refrigerant, or other types of heat-carrying fluids, can travel to cool technical fluid, that is being warmed by heated electronic devices (e.g., CPU, GPU, etc.), passing through the electronic devices.

For instance, referring to FIG. 4, a server rack assembly 400 according to another embodiment of the present disclosure may include a server rack 402 securely holding rack mountable systems. In some embodiments, the rack-mountable systems may be, e.g., high-power central processing units (CPUs), graphical processing units (GPUs), a server blade, a power supply unit, a keyboard, video, and mouse (KVM) switch, a network patch panel, or the like. One or more cold plates 404, 406 may be arranged, directly or indirectly, on the corresponding rack mountable systems. In addition, although not shown, one or more cooling fans may be provided on the server rack 402 to provide additional air cooling to computing nodes. Thus, as a hybrid liquid-air cooling system, a portion of the heat generated by the rack-mountable systems can be removed by cooling liquid via the corresponding cold plates while the remaining portion of the heat generated by the rack-mountable systems can be removed by airflow cooling. In various embodiments, the cold plates can be any suitable type of cold plate, such as a tubed cold plate or a cold plate comprising internal fins or channels (e.g., microchannels), and may be made of any suitable material, such as copper, aluminum, or stainless steel, that is chemically compatible with immersion and working fluids.

In detail, the rack mountable systems may a heat-generating electronic device including one or more IT components (e.g., central processing units or CPUs, graphical processing units (GPUs), memory, and/or storage devices). Each IT component may perform data processing tasks, where the IT component may include software installed in a storage device, loaded into the memory, and executed by one or more processors to perform the data processing tasks. Further, the server blade may include a host server (referred to as a host node) coupled to one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the performance computing nodes or compute servers (having one or more GPUs) managed by the host server. The performance compute servers perform the actual tasks, which may generate heat during the operations.

In some embodiments, the technical fluid is distributed through a liquid distribution loop 408 communicating with the cold plates 404, 406 on which the rack mountable systems are respectively mounted to remove heat therefrom. The cold plates 404, 406 may be configured similar to a heat sink with a liquid distribution tube attached or embedded therein. In some embodiments, the server rack assembly 400 may further include a pump 410 on the liquid distribution loop 408, a pump controller (not shown), and some other components, such as a liquid reservoir, a power supply, monitoring sensors 424, and so on.

The technical fluid flows through a supply fluid path 408a of the liquid distribution loop 408 and the cold plates 404, 406 attached to the rack-mountable systems, where it absorbs heat generated by these components, and follows a return fluid path 408b of the liquid distribution loop 408 back to the pump 410. The pump 410 and cold plates 404, 406 may thus be placed atop components such as central processing units (CPUs), graphics processing units (GPUs), or memory units. In various embodiments, the CPUs and memory can be water-cooled, with the balance of the hardware being air-cooled. In forced convection embodiments, a single pump can be used to circulate the technical fluid. In some embodiments, multiple pumps can be used to circulate the technical fluid. The technical fluid may include H2O or may include more viscous fluids than water like ethylene glycol and water (EGW), oils, 3M Fluorinert®, Polyalphaolefin (PAO), a Propylene Glycol mixture, or the like. The pump 410 may circulate such a technical fluid through the liquid distribution loop 408 passing through the cold plates 404, 406 at certain rates. The technical fluid passing through the cold plates 404, 406 is then heated by the electronic devices and can be cooled by a heat exchanger which will be described hereinbelow.

In some embodiments, a stackable coolant distribution unit (CDU) 412 (hereinafter, simply a “heat exchanger”), may be assembled to the server rack 402 at one end as shown in FIG. 4. The heat exchanger 412 may have a tube shape or coil shape within which a fluid travels and may have an inlet 414 and an outlet 416 at opposite ends. The fluid travels within the heat exchanger 412 may be water or any ethylene glycol-based fluids. As shown, a portion of the liquid distribution loop 408 may be in contact with the heat exchanger 412. For instance, the return fluid path 408b carrying hot technical fluid may be in contact with the heat exchanger 412, e.g., a main body 426 of the loop 408, carrying cold fluid. The hot fluid inside the return fluid path 408b then cools down as passing by the main body 426 of the heat exchanger 412 before returning to the pump 410. In some embodiments, the fluid can enter the heat exchanger 412 via the inlet 414 as shown by arrow 418 flow to the outlet 416 to exit out as shown by arrow 420.

According to some embodiments, the server rack assembly 400 may communicate with a controller. For instance, the server rack assembly 400 may communicate with a computer system (see “604” in FIGS. 6A and 6B) having a controller located inside the data center but outside the server rack assembly 400. The controller may periodically or constantly monitor the operating status of the server rack 402 and the heat exchanger 412. The operating data of the operating status may include the operating temperatures of each processor, cooling liquid, an airflow, etc., measured at real-time.

For instance, referring back to FIG. 4, there may be various sensors 424 installed along the liquid distribution loop 408, on the pump 410, on the cold plates 404, 406, on the heat exchanger 412, etc., for obtaining various sensing data. The sensing data may include, but not limited to, a fluid contamination (particle) sensor, a temperature sensor, a flow rate sensor, a voltage sensor, a speedometer, etc. Based on the operating data received from various components, the controller may perform an optimization using an optimization function to determine the optimal pump speed of a liquid pump of the CDU and optimal fan speeds of the cooling fans, if any, such that the power consumption of the liquid pump and the cooling fans reaches the minimum, while the liquid pump and the cooling fans are operating properly according to their respective specifications (e.g., the speeds of the liquid pump and cooling fans are within their respective predefined ranges). According to the server rack assembly 400 of the present disclosure, one server 402 is cooled by the respective or corresponding technical fluid provided by a designated pump (e.g., 410) and a designated heat exchanger (e.g., 412). Thus, when there is a fault in the technical fluid, the pump, and/or the cold plates in that server, only that specific server is impacted. This feature will be described further below with reference to FIGS. 5, 6A, and 6B.

In various embodiments, a computing system (e.g., “604” in FIGS. 6A and 6B), which can provide working fluid flow rate control or gas pressure control in a hybrid liquid computing system, may communicate with the server rack assembly 400 and the heat exchanger 412. The computing system may be a multiprocessor system comprising processor units. The processor units comprise multiple processor cores. The processor units can execute computer-executable programs. The computing system can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein. Further, in some embodiments, the computing system can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

FIG. 5 illustrates one rack system 500 configured by stacking several server rack assemblies 400 of FIG. 4. A number of servers 402 can be stacked vertically on top of each other while the heat exchangers 412 can be vertically assembled to each other by connecting an inlet 414a of one heat exchanger 412 to an inlet 414b of another heat exchanger 412, and an outlet 416a of one heat exchanger 412 to an outlet 416b of another heat exchanger 412. Inlets and outlets of the heat exchangers have openings through which fluid can pass. In some embodiments, an inlet of the very top heat exchanger is however not through-hole formed so that the fluid can only travel in the lateral direction. The heat exchangers 412 are respectively connected to or in contact with the corresponding liquid distribution loops 408. Here, the liquid distribution loops 408 do not communicate with one another, but merely in contact with the respective servers 402. In various embodiments, the number of servers and heat exchangers can vary based on the size and need of the overall system, such that there can be 1 server and 1 corresponding heat exchanger, 2 servers and 2 corresponding heat exchangers, 3 servers and 3 corresponding heat exchangers, etc.

In some embodiments, fluid entering the inlet 414a as represented by arrow 418a may flow up to the inlet of the above heat exchanger as represented by arrow 418b and may also flow toward the outlet 416a through a tunnel of the heat exchanger 412 as represented by arrow 422. For example, when 100% of the fluid initially is supplied through the inlet 414a, 80% of the fluid may flow to the inlet 414b while 20% thereof may flow toward the outlet 416a. The amount of fluid and/or flowrate thereof may vary and be controlled by the above-described controller based on various factors, e.g., temperature, power, number of servers, etc. The fluid laterally flowing as arrow 422 in each heat exchanger 412 may have the same amount of fluid. In various embodiments, the heat exchanger may be, without limiting thereto, a double-pipe heat exchanger, a shell-and-tube heat exchanger, a plate heat exchanger, a condensers and boilers heat exchanger using a two-phase heat transfer system, etc. In addition, heat exchangers or similar units for producing steam from water are often called boilers or steam generators.

By the above-described configuration, each server is separately cooled by its own pump and the technical fluid, while the heated technical fluid can be cooled via stackable heat exchanger assembly that can collectively deliver the fluid.

FIGS. 6A and 6B illustrate a rack system 600 having an enclosed server rack cabinet 602 in which the CDUs or the stackable heat exchangers with and without servers, respectively, are installed in the cabinet 602. The rack cabinet 602 may correspond to the computer cabinet 100 that includes the server rack 136 as shown in FIGS. 1A and 1B in accordance with an exemplary embodiment of the present disclosure. In addition, similar to the CDU 124 of an embodiment, the rack system 500 may be located in a rear, side, or front space of the computer cabinet 602 whereas it can be considered a “zero u” space similar to the computer cabinet 100.

In some embodiments, as also described above, the rack system 600 may communicate with an externally located computer system 604 which includes various processors and which communicates with various sensors 606. However, it is not limited to the external connection as described, but the computer system 604 and the various sensors 606 however may be located inside the rack cabinet 602. Based on sensing data detected by the various sensors 606, the controller may determine whether to turn off any one or more of the systems. For instance, if contamination is detected in a technical fluid for one of the servers, the controller may control a valve (not shown) to turn off the supply of technical fluid for that specific server without interfering with other servers, while the stackable CDU system can continuously provide heat exchange to each server. This allows not only being able to individually monitor and control each server having separately configured cold plates and pump, but also being able to control the technical fluid volume/speed passing through the loop 408, thus providing several benefits over a conventional system where there is only one pump connected to each server such that when there is a fault, all servers in the rack is affected or the technical fluid supply to all servers needs to be entirely turned off.

Further, although the computer cabinet 602 of another embodiment may be similar to the computer cabinet 100 of an embodiment, the computer cabinet 602 may not need top openings 108 as input and exhaust features are not needed. In addition, unlike the server rack assembly of an embodiment having pumps and heat exchanger inside the CDU 124, the rack system 500 according to another embodiment has a pump installed on the server while heat exchangers are stacked in the zero-u space for supplying colder fluid. This configuration allows the amount of the technical fluid provided on the server to be dramatically decreased, and each server can be on a smaller loop. The reduction in volume greatly reduces the likelihood of fouling and air entrapment taking down an entire rack or row of racks. This configuration also allows for easier service and troubleshooting of an individual server. This is generally considered a decrease in “blast radius” as each CDU only affects one rack. In this design the in-row manifold would no longer be at risk of causing fouling to the delicate cold plates, allowing the in-row manifold to be much less expensive and less critical.

In addition, according to the stackable heat exchanger assembly of the present disclosure in which one or more cold plates are connected before the fluid contacts the heat exchanger, cold plates can be integrated with a pump. Accordingly, the heat rejection can double as the in-rack manifold, and the amount of technical fluid is greatly reduced.

The above-described hybrid CDU rack system can offer an alternate solution to direct-to-chip liquid cooling that reduces certain issues created by existing solutions. Solving these problems will result in higher sales by making direct-to-chip cooling easier to implement. Price may be less, but the simplicity and reduction of blast radius could be integral to messaging to increase market share.

Row-based CDUs, which can serve multiple racks of highly sensitive GPU-based compute load, are undesirably large, complex machines with pumps, filters, controls, and redundancy to allow concurrent maintainability. As such, any issues affecting the CDU can affect the entire cluster. Failure to maintain fluid flow in the event of a fault can risk damaging dozens to hundreds of GPUs which can quickly overheat and go into thermal protection mode. Having a technical fluid piping network with over, e.g., 500 cold plates, and hundreds of gallons of fluid can be difficult to manage and commission. Cold plates can lose cooling due to air becoming trapped within the cold plate and the small tubing, debris clogging the channels of the cold plate, uneven pressure drop across all cold plates (piping and height differences), and many other reasons. Loss of cooling across a cold plate even for one second can damage the IT hardware. As such, all of the components included in the IT cooling loop can be referred to as the ‘Blast Radius’—the array of IT Gear that is affected by a failure in the CDU.

Reducing the blast radius of the CDU to a single rack as described above can offer more autonomy to the cluster deployment. Further, if each cold plate is capable of pumping its own fluid, the CDU can become a passive component, and further reduce the blast radius to individual pumped cold plates affecting very few GPUs.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules or controllers can be implemented as circuitry, such as gas pressure controller circuitry or working fluid flow rate controller circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C #, Java, Perl, Python, JavaScript, Adobe Flash, C #, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

What is claimed is:

1. A server rack assembly comprising:
a housing in which a rack is enclosed;
a first server disposed on the rack and configured to support a heat-generating electronic device, wherein the first server comprises a cold plate disposed on the heat-generating electronic device and a pump fluidically communicating with the cold plate via a liquid distribution loop; and
a first coolant distribution unit (CDU) configured to be assembled to the first server, wherein the first CDU is configured to be in contact with the liquid distribution loop and comprises an inlet and an outlet,
wherein the pump is configured to direct a technical fluid to flow from the pump, to the cold plate, and back to the pump.

2. The server rack assembly of claim 1, further comprising:
a second server configured to be disposed adjacent the first server on the rack, the second server having a pump, a cold plate, and a liquid distribution loop therebetween; and
a second CDU configured to be assembled to the second server,
wherein an inlet and an outlet of the second CDU and the inlet and the outlet of the first CDU, respectively, are configured to correspond to each other.

3. The server rack assembly of claim 2, further comprising:
a third server configured to be disposed adjacent the second server on the rack, the third server having a pump, a cold plate, and a liquid distribution loop therebetween; and
a third CDU configured to be assembled to the third server,
wherein an inlet and an outlet of the third CDU and the inlet and the outlet of the second CDU, respectively, are configured to correspond to each other.

4. The server rack assembly of claim 1, wherein the first to third CDUs are disposed in a space adjacent the first to third servers within the housing.

5. The server rack assembly of claim 3, further comprising a controller and a sensor communicating with each of the first to third CDUs and the first to third servers.

6. The server rack assembly of claim 5, further comprising a user interface on the controller for manual control and monitoring of cooling parameters.

7. The server rack assembly of claim 5, wherein the controller is configured to control the fluid to partly flow vertically through inlets of the first to third CDUs and to partly flow laterally from the inlets to the outlets, respectively, of the first to third CDUs.

8. The server rack assembly of claim 5, wherein an amount and a flow rate of fluid flowing through the first to third CDUs are controlled by the controller based on sensing data received from the sensor.

9. The server rack assembly of claim 8, wherein the sensing data includes at least one of a cold plate status, a fluid flow rate, a heat-generating electronic device status, a fluid temperature, or a fluid particle size.

10. The server rack assembly of claim 8, wherein, based on the sensing data, the controller is configured to selectively control the pumps of the respective first to third servers.

11. The server rack assembly of claim 8, wherein, when the sensing data detected by the first server is outside a threshold, the controller turns off the pump of the first server.

12. The server rack assembly of claim 11, wherein, when the sensing data detected by the second server is outside a threshold, the controller turns off the pump of the second server.

13. The server rack assembly of claim 1, wherein the first server further comprises a second cold plate disposed on a second heat-generating electronic device.

14. The server rack assembly of claim 13, wherein the first server further comprises a second pump, wherein the first and second pumps communicate with the first and second cold plates, respectively, on the first server.

15. The server rack assembly of claim 1, wherein the inlet has an opening at a bottom side of the CDU and the outlet has an opening at a top side of the CDU.

16. A stackable server assembly for liquid cooling comprising:
at least two cold plates disposed on heat-generating electronic devices, respectively;
a pump configured to provide a technical fluid to the least two cold plates via a supply fluid path and receive the technical fluid that passes through the least two cold plates via a return fluid path; and
a heat exchanger extending along one side of the server,
wherein the heat exchanger comprises a main body.

17. The server rack assembly of claim 16, wherein the heat exchanger comprises an inlet, an outlet, and a main body extending between the inlet and the outlet.

18. The server rack assembly of claim 17, wherein the heat exchanger is configured as a tube through which a fluid passes from the inlet to the outlet.

19. The server rack assembly of claim 17, wherein the main body of the heat exchanger is in direct contact with the return fluid path.

20. The server rack assembly of claim 17, wherein the inlet and the outlet of the heat exchanger are configured to correspond to an inlet and an outlet of another heat exchanger, respectively, to be assembled.
